(19) United States
(12) Patent Application Publication
(10) Pub. No.: US 2022/0199581 A1
(43) Pub. Date: Jun. 23, 2022

(54) MULTI-DIE PACKAGE STRUCTURE AND MULTI-DIE CO-PACKING METHOD

(71) Applicant: Chengdu Monolithic Power Systems Co., Ltd., Chengdu (CN)

(72) Inventors: Yingjiang Pu, Chengdu (CN); Hunt Jiang, Saratoga, CA (US)

(21) Appl. No.: 17/544,075

(22) Filed: Dec. 7, 2021

(30) Foreign Application Priority Data
Dec. 23, 2020 (CN) 202011534093.8

(51) Int. Cl. H01L 25/065; H01L 23/538; H01L 23/00; H01L 25/00

(52) U.S. Cl. CPC H01L 25/0657; H01L 23/5383; H01L 2224/16145; H01L 24/16; H01L 25/50; H01L 23/5389

(57) ABSTRACT

A multi-die package structure with an embedded die embedded in a substrate, a high flip chip die mounted above the substrate, and a low flip chip die placed below the substrate. The package is compact and low cost.

### CROSS-REFERENCE TO RELATED APPLICATIONS

This application claims priority to and the benefit of Chinese Patent Application No. 202011534093.8, filed Dec. 23, 2020, which is incorporated herein by reference in its entirety.

### FIELD

The present invention relates to semiconductor packages, and more particularly relates to multi-die package structures.

### BACKGROUND

The requirements for customer electronics products have increased significantly in recent years. Miniaturization and portability are overwhelming trends which push the IC package to be more compact. Accordingly, the electronic portable devices become smaller and smaller along with more functions and better performances. Thus, today's power supply systems are required to have smaller size along with higher power output, more functions and better efficiency. Under these requirements, some technology incorporate switching devices such as FETs and controllers into a monolithic die. However, the controllers typically adopt CMOS process which may need 18-20 masks during fabrication, while the FETs typically adopt DMOS process which needs 8-9 masks during the fabrication. So such monolithic die costs a lot in order to fabricate the FETs together with the controller.

### SUMMARY

It is an object of the present invention to provide a solution, which solves the above problems.

In accomplishing the above and other objects, there has been provided, in accordance with an embodiment of the present invention, a multi-die package structure, comprising: an embedded die, configured to be embedded in a substrate; a high flip chip die, configured to be mounted above the substrate, the high flip chip die being electrically coupled to the substrate by way of a first conductor; and a low flip chip die, configured to be placed below the substrate, the low flip chip die being electrically coupled to the substrate by way of a second conductor.

In accomplishing the above and other objects, there has been provided, in accordance with an embodiment of the present invention, a multi-die co-packed chip, comprising: an input pin, configured to receive an input voltage, the input pin electrically coupled to a first die on which a high side power switch is fabricated; a switch pin, electrically coupled to the first die and a second die on which a low side power switch is fabricated; a ground pin, electrically coupled to the second die; and a control pin, configured to receive a control signal, the control pin electrically coupled to a third die on which a control circuit is fabricated; wherein either one of the first die, the second die or the third die is embedded in a substrate as an embedded die; and wherein either one of the remaining two dies is mounted above the substrate as a high flip chip die, and the remaining die is placed below the substrate as a low flip chip die.

In accomplishing the above and other objects, there has been provided, in accordance with an embodiment of the present invention, a multi-die co-packing method, comprising: embedding an embedded die in a substrate, the substrate having multiple metal layers; mounting a high flip chip die over the substrate; placing a low flip chip die below the substrate; electrically coupling the embedded die, the high flip chip die, the low flip chip die and the substrate by way of conductors; and molding the embedded die, the high flip chip die, the low flip chip die, and the substrate as a package.

### BRIEF DESCRIPTION OF THE DRAWINGS

FIG. 1 schematically shows a sectional view of a multi-die package structure 100 in accordance with an embodiment of the present invention.

FIG. 2 schematically shows a sectional view of a multi-die package structure 200 in accordance with an embodiment of the present invention.

FIG. 3 schematically shows a sectional view of a multi-die package structure 300 in accordance with an embodiment of the present invention.

FIG. 4 schematically shows a sectional view of a multi-die package structure 400 in accordance with an embodiment of the present invention.

FIG. 5 schematically shows a sectional view of a multi-die package structure 500 in accordance with an embodiment of the present invention.

FIG. 6 schematically shows a sectional view of a multi-die package structure 600 in accordance with an embodiment of the present invention.

FIG. 7 schematically shows a sectional view of a multi-die package structure 700 in accordance with an embodiment of the present invention.

FIG. 8 schematically shows a sectional view of a multi-die package structure 800 in accordance with an embodiment of the present invention.

FIG. 9 schematically shows a buck converter 900 in accordance with an embodiment of the present invention.

FIG. 10 schematically shows a flowchart 1000 of a multi-die co-packing method in accordance with an embodiment of the present invention.

The use of the similar reference label in different drawings indicates the same of like components.

### DETAILED DESCRIPTION

Embodiments of circuits for multi-die package structure incorporating embedded die and flip chip dies are described in detail herein. In the following description, some specific details, such as example circuits for these circuit components, are included to provide a thorough understanding of embodiments of the invention. One skilled in relevant art will recognize, however, that the invention can be practiced without one or more specific details, or with other methods, components, materials, etc.

The following embodiments and aspects are illustrated in conjunction with circuits and methods that are meant to be exemplary and illustrative. In various embodiments, the above problem has been reduced or eliminated, while other embodiments are directed to other improvements.

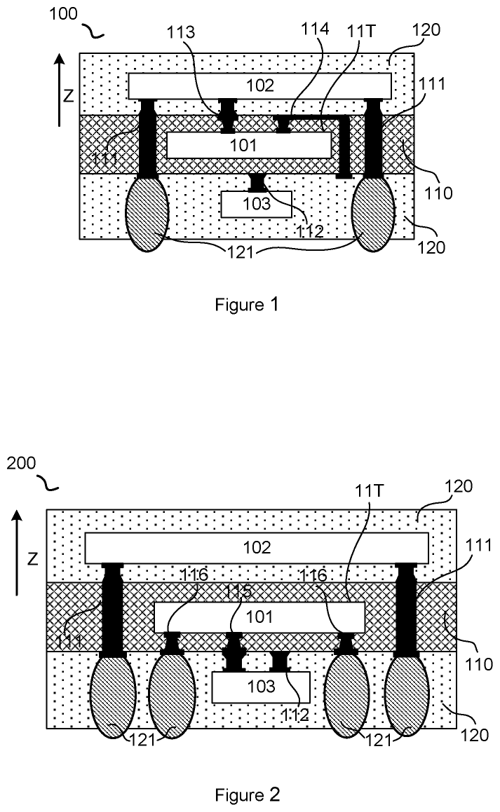

FIG. 1 schematically shows a sectional view of a multi-die package structure 100 in accordance with an embodiment of the present invention. In the example of FIG. 1, the multi-die package structure 100 comprises: an embedded die 101, configured to be embedded in a substrate 110; a high flip chip die 102, configured to be mounted above the substrate 110, the high flip chip die 102 being configured to contact with the substrate 110 by way of a first conductor 111 (e.g., a contact bump, or a through via, or a metal trace); a low flip chip die 103, configured to be placed below the substrate 110 (e.g., attached to a bottom surface of the substrate), the low flip chip die 103 being configured to contact with the substrate 110 by way of a second conductor 112.

In one embodiment of the present invention, the first conductor 111 may be lead out by way of a solder ball 121.

In one embodiment of the present invention, integrated circuit/circuits and electric contact pads (e.g. contact bumps) are formed on an active surface (first surface) 11T of the embedded die 101. In one embodiment of the present invention, this active surface is also called as an upper surface or as a top surface; and the embedded die 101 also has a second surface opposite to the first surface, which is also called as a bottom surface.

One skilled in the art should realize that the term “flip chip die” in one embodiment may include any die that the contact area of the die directly connects with lead frame structure or package substrate by bump; the term “high flip chip die” may refer to a flip chip die having an active surface facing down; the term “low flip chip die” may refer to a flip chip having an active surface facing up; the term “substrate” may refer to a package-level material similar as that used in a printed circuit board (PCB), which typically has multiple metal layers; and the term “contact bump” may refer to a small metal solid in a ball or pillar shape usually comprises the solder material used to directly connect two contact areas.

In one embodiment of the present invention, vias are added in the dies and in the substrate, which are then filled with metal material such as copper, to form metal traces between different dies, between the dies and the substrate, and between the dies and the external contact.

In one embodiment of the present invention, the active surface 11T of the embedded die 101 may face up (face to the high flip chip die 102, as shown in FIG. 1), or face down (face to the low flip chip die 103, as shown in FIG. 2). As shown in FIG. 1, when the active surface 11T of the embedded die 101 faces up, the active surface 11T of the embedded die 101 is configured to contact with the high flip chip die 102 by way of a third conductor 113, and is configured to contact with the substrate 110 by way of a fourth conductor 114. As shown in FIG. 2, when the active surface 11T of the embedded die 101 faces down, the active surface 11T of the embedded die 101 is configured to contact with the low flip chip die 103 by way of a fifth conductor 115, and is configured to contact with the substrate 110 by way of a sixth conductor 116.

In one embodiment of the present invention, the fourth conductor 114 is led out from the bottom surface of the substrate 110 by way of metal traces and through vias, so as to act as an input and/or an output terminal of the embedded die 101.

In one embodiment of the present invention, the multi-die package structures 100 and 200 further comprise: molding material 120, encapsulating and protecting the high flip chip die 102, the low flip chip die, and the substrate 110. In one embodiment of the present invention, molding material comprises a kind of electrical insulation material such as epoxy.

In one embodiment of the present invention, partial periphery of the embedded die 101 is overlapped with partial periphery of the high flip chip die 102 and partial periphery of the low flip chip die 103 in vertical direction (Z direction as shown in FIGS. 1 & 2), i.e., the embedded die 101 has an active surface that is at least partly overlapped by the high flip chip die 102 and a bottom surface opposite to the active surface, and the bottom surface is at least partly overlapped by the low flip chip die 103, so that the conductor between the high flip chip die 102 and the embedded die 101 (or the conductor between the low flip chip die 103 and the embedded die 101) has shortest vertical contact bump and less parasitic resistance.

In one embodiment of the present invention, the vertical direction is a direction vertical to the die plane, i.e., vertical to the active surface of the embedded die 101.

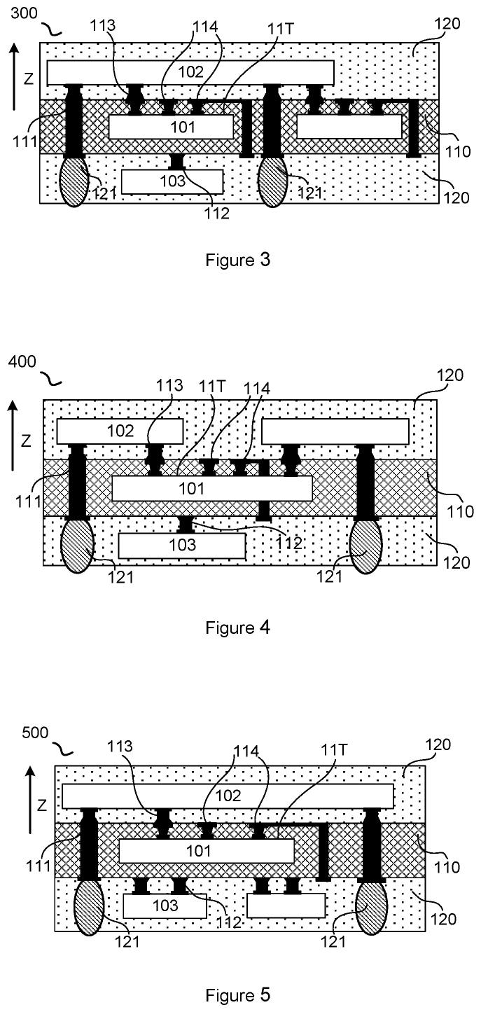

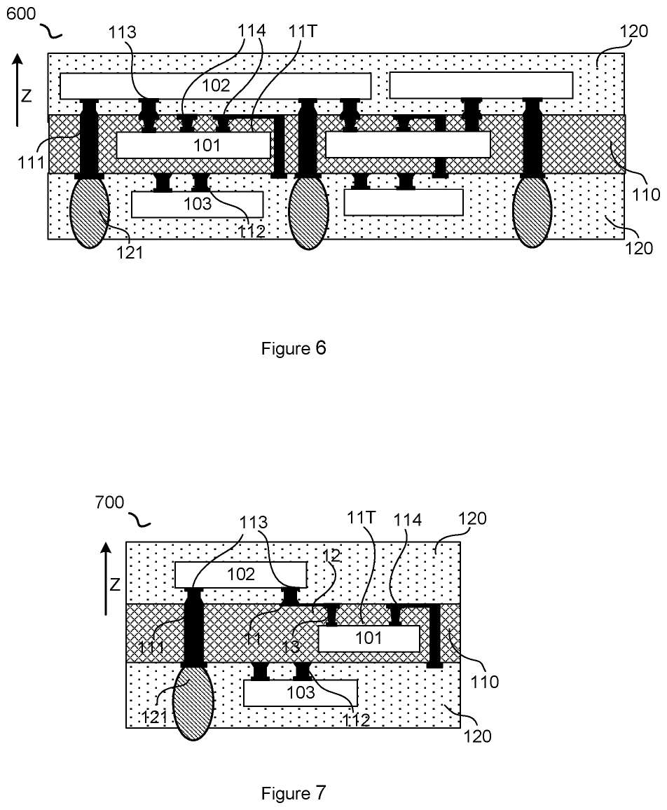

The foregoing multi-die package structures shown in the embodiments of FIG. 1 and FIG. 2 have one embedded die with one high flip chip die and one low flip chip die co-packed in one package outline. However, one skilled in the art should realize that in other embodiments of the present invention, the multi-die package structure may comprise one or more embedded dies with one or more high flip chip dies, and one or more low flip chip dies co-packed in one package outline. As schematically shown in FIGS. 3-6, sectional views of multi-die package structures 300, 400, 500 and 600 are illustrated. These embodiments schematically show the combination of one or two embedded dies with one or two high flip chip dies and one or two low flip chip dies. However, one skilled in the art should realize that in other embodiments of the present invention, the multi-die package structure may comprise any desired number of embedded dies, high flip chip dies, and low flip chip dies co-packed in one package outline.

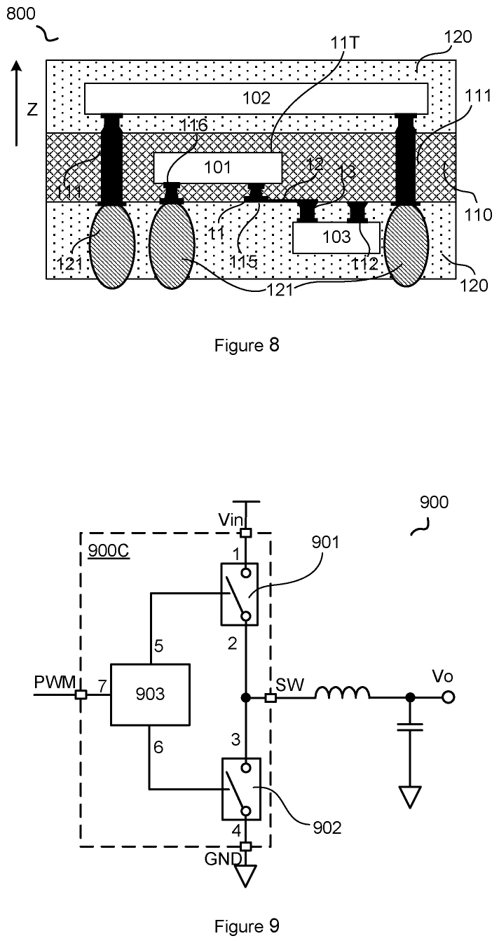

Several embodiments of the foregoing multi-die package structure have partial periphery of the embedded die 101 be overlapped with partial periphery of the high flip chip die 102 and partial periphery of the low flip chip die 103 in vertical direction. However, one skilled in the art should realize that in other embodiments of the present invention, the embedded die 101, the high flip chip die 102 and the low flip chip die 103 may not be overlapped with each other in vertical direction, as shown a multi-die package structure 700 in FIG. 7 and a multi-die package structure 800 in FIG. 8.

The multi-die package structure 700 shown in FIG. 7 is similar as the multi-die package structure 100 shown in FIG. 1, with a difference that, in the multi-die package structure 700, the embedded die 101 has no overlap with the high flip chip die 102 in vertical direction; and the third conductor 113 between the embedded die 101 and the high flip chip die 102 comprises: a contact bump 11 (the part that contacts with the high flip chip die 102 in vertical direction), a metal trace 12 (in planar direction) and a via structure (or contact bumps) 13 (the part that contacts with the embedded chip die 101 in vertical direction).

The multi-die package structure 800 shown in FIG. 8 is similar as the multi-die package structure 200 shown in FIG. 2 with a difference that, in the multi-die package structure 800, the embedded die 101 has no overlap with the low flip chip die 103 in vertical direction; and the fifth conductor 115 between the embedded die 101 and the low flip chip die 103 comprises: a via structure (or contact bumps) 11 (the conductor part that contacts with the embedded chip die 101 in vertical direction), a metal trace 12 (in planar direction) and a contact bump 13 (the conductor part that contacts with the low flip chip die 102 in vertical direction).

In one embodiment of the present invention, the embedded die 101, the high flip chip die 102 and the low flip chip die 103 may respectively comprise switch power devices and a controller operable to control the switch power devices. For example, the embedded die 101 and the high flip chip die 102 may respectively comprise a switch power device, and the low flip chip die 103 may comprise the corresponding controller; or the high flip chip die 102 and the low flip chip die 103 may respectively comprise a switch power device, and the embedded die 101 may comprise the corresponding controller; or the embedded die 101 and the low flip chip die 103 may respectively comprise a switch power device, and the high flip chip die 102 may comprise the corresponding controller. One skilled in the art should realize that in other embodiments of the present invention, the embedded die 101, the high flip chip die 102 and the low flip chip die 103 may comprise other any desired circuits and devices.

FIG. 9 schematically shows a buck converter 900 in accordance with an embodiment of the present invention. In the example of FIG. 9, the buck converter 900 comprises: a multiple-die co-packed chip 900C including: an input pin Vin, configured to receive an input voltage, the input pin Vin electrically coupled to a first die 901 on which a high side power switch is fabricated; a switch pin SW, electrically coupled to the first die 901 and a second die 902 on which a low side power switch is fabricated; a ground pin GND, electrically coupled to the second die 902; and a control pin PWM, configured to receive a control signal (e.g. from a pre-stage), the control pin PWM electrically coupled to a third die 903 on which a control circuit is fabricated; wherein either one of the first die 901, the second die 902 or the third die 903 is embedded in a substrate as an embedded die, and wherein either one of the remaining two dies is mounted above the substrate as a high flip chip die, and the remaining die is placed below the substrate (e.g., attached or mounted to the bottom surface of the substrate) as a low flip chip die.

In one embodiment of the present invention, the high side power switch and the low side power switch are controlled by the control circuit.

Continue referring to FIG. 9, the first die 901 having a first terminal 1 electrically coupled to the input pin Vin, a second terminal 2 electrically coupled to the switch pin SW, and a control terminal electrically coupled to the third die 903. The second die 902 having a first terminal 3 electrically coupled to the switch pin SW, a second terminal 4 electrically coupled to the ground pin GND, and a control terminal electrically coupled to the third die 903. The third die 903 having an input terminal 7 electrically coupled to the control pin PWM, a first output terminal 5 electrically coupled to the control terminal of the first die 901, and a second output terminal 6 electrically coupled to the control terminal of the second die 902.

In one embodiment of the present invention, the buck converter 900 further comprises an inductor and an output capacitor, both coupled to the switch pin SW of the multi-die package chip 900C, to provide an output voltage Vo.

Several embodiments of the foregoing multi-die package structure provide much compact solution for smaller package size and less parasitic RLC (resistance, inductance and capacitance), which brings better performance. Unlike the conventional technique, several embodiments of the foregoing multi-die package structure may adopt different processes to fabricate different dies (e.g., the flip chip die with one process and the embedded die with another process), and then co-pack the dies together with some of the dies embedded in the substrate, and the other dies mounted above or below the substrate, and contacting with the embedded dies and with the substrate through contact bumps. Thus the total cost is down. In addition, the embedded die is overlapped with the high flip chip die and the low flip chip die partially in a direction vertical to the die plane, resulting a smaller package size, which further saves the cost.

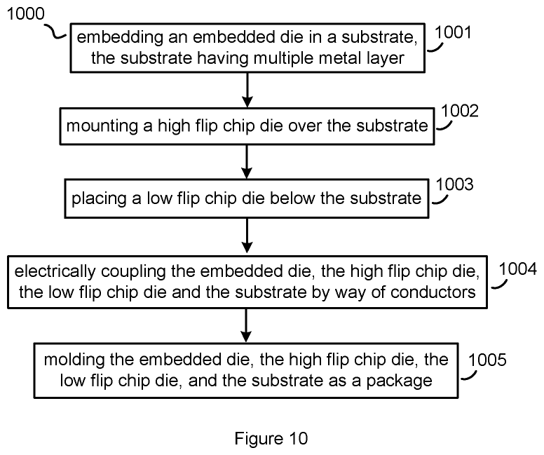

FIG. 10 schematically shows a flowchart 1000 of a multi-die co-packing method in accordance with an embodiment of the present invention. The method comprising:

Step 1001, embedding an embedded die in a substrate, the substrate having multiple metal layers.

Step 1002, mounting a high flip chip die over the substrate.

Step 1003, placing a low flip chip die below the substrate (e.g. attaching the low flip chip die to a bottom surface of the substrate).

Step 1004, electrically coupling the embedded die, the high flip chip die, the low flip chip die and the substrate by way of conductors. And

Step 1005, molding the embedded die, the high flip chip die, the low flip chip die, and the substrate as a package.

In one embodiment of the present invention, the method further comprising pre-planting solder balls at the bottom surface of the substrate.

In one embodiment of the present invention, the conductor comprises contact bumps, via structure and/or metal traces. In another embodiment of the present invention, the conductor comprises contact bump and through vias.

In one embodiment of the present invention, the embedded die, the high flip chip die, and the low flip chip die is respectively led out through different metal layers of the substrate, to act as external pins.

In one embodiment of the present invention, at least partial periphery of the embedded die is overlapped with partial periphery of the high flip chip die, and with partial periphery of the low flip chip die in vertical direction perpendicular with the embedded die.

It is to be understood in these letters patent that the meaning of “A” is coupled to “B” is that either A and B are connected to each other as described below, or that, although A and B may not be connected to each other as described above, there is nevertheless a device or circuit that is connected to both A and B. This device or circuit may include active or passive circuit elements, where the passive circuit elements may be distributed or lumped-parameter in nature. For example, A may be connected to a circuit element that in turn is connected to B.

This written description uses examples to disclose the invention, including the best mode, and also to enable a person skilled in the art to make and use the invention. The patentable scope of the invention may include other examples that occur to those skilled in the art.

What is claimed is:

1. A multi-die package structure, comprising:
an embedded die, configured to be embedded in a substrate;
a high flip chip die, configured to be mounted above the substrate, the high flip chip die being electrically coupled to the substrate by way of a first conductor; and
a low flip chip die, configured to be placed below the substrate, the low flip chip die being electrically coupled to the substrate by way of a second conductor.

2. The multi-die package structure of claim 1, wherein:
the substrate comprises multiple layers, and the embedded die, the high flip chip die, and the low flip chip die is respectively led out through different metal layers of the substrate, to act as external pins.

3. The multi-die package structure of claim 1, wherein:
the embedded die has an active surface, wherein the active surface is at least partly overlapped by the high flip chip die; and
the embedded die has a bottom surface opposite to the active surface, wherein the bottom surface is at least partly overlapped by the low flip chip die.

4. The multi-die package structure of claim 1, wherein the embedded die has an active surface facing down to the low flip chip die, and wherein the active surface is electrically coupled to the substrate and the low flip chip die by way of the second conductor.

5. The multi-die package structure of claim 4, wherein the second conductor comprises a contact bump, a via structure and a metal trace.

6. The multi-die package structure of claim 1, wherein the embedded die has an active surface facing up to the high flip chip die, and wherein the active surface is electrically coupled to the substrate and the high flip chip die by way of the first conductor.

7. The multi-die package structure of claim 6, wherein the first conductor comprises a contact bump, a via structure and a metal trace.

8. A multi-die co-packed chip, comprising:
an input pin, configured to receive an input voltage, the input pin electrically coupled to a first die on which a high side power switch is fabricated;
a switch pin, electrically coupled to the first die and a second die on which a low side power switch is fabricated;
a ground pin, electrically coupled to the second die; and
a control pin, configured to receive a control signal, the control pin electrically coupled to a third die on which a control circuit is fabricated; wherein
either one of the first die, the second die or the third die is embedded in a substrate as an embedded die; and wherein
either one of the remaining two dies is mounted above the substrate as a high flip chip die, and the remaining die is placed below the substrate as a low flip chip die.

9. The multi-die co-packed chip of claim 8, wherein:
the embedded die has an active surface, the active surface being at least partly overlapped by the high flip chip die; and
the embedded die has a bottom surface opposite to the active surface, the bottom surface at least partly overlapped by the low flip chip die.

10. A multi-die co-packing method, comprising:
embedding an embedded die in a substrate, the substrate having multiple metal layers;
mounting a high flip chip die over the substrate;
placing a low flip chip die below the substrate;
electrically coupling the embedded die, the high flip chip die, the low flip chip die and the substrate by way of conductors; and
molding the embedded die, the high flip chip die, the low flip chip die, and the substrate as a package.

11. The multi-die co-packing method of claim 10, wherein:
the embedded die has an active surface, the active surface being at least partly overlapped by the high flip chip die; and
the embedded die has a bottom surface opposite to the active surface, the bottom surface at least partly overlapped by the low flip chip die.

12. The multi-die co-packing method of claim 10, wherein:
the conductor comprises a contact bump, a via structure and/or metal traces.

13. The multi-die co-packing method of claim 10, wherein:
the conductor comprises a contact bump and a through via.

14. The multi-die co-packing method of claim 10, wherein:
the embedded die, the high flip chip die, and the low flip chip die is respectively led out through different metal layers of the substrate, to act as external pins.
